(19) United States
(12) Patent Application Publication
(10) Pub. No.: US 2007/0007122 A1
(43) Pub. Date: Jan. 11, 2007

(54) System and method for forming thin film metal layers in vias

(75) Inventor: David A. Rothenbury, Garland, TX (US)

Correspondence Address: TEXAS INSTRUMENTS INCORPORATED, P O BOX 655474, M/S 3999, DALLAS, TX, 75265, US

(73) Assignee: TEXAS INSTRUMENTS INCORPORATED

(21) Appl. No.: 11/174,895

(22) Filed: Jul. 5, 2005

(51) Int. Cl. C23C 14/32; C23C 14/00

(52) U.S. Cl. 204/192.1; 204/298.02

(57) ABSTRACT

In one embodiment, a method for forming a metal layer in a via of a semiconductor device includes providing a substrate, the substrate having a plurality of vias formed therein, forming a first portion of a metal layer outwardly from the substrate using a long throw sputtering process, and forming a second portion of the metal layer outwardly form the first portion of the metal layer using a short throw sputtering process. The first and second portions of the metal layer equal a total thickness of the metal layer.

### TECHNICAL FIELD OF THE INVENTION

This invention relates in general to semiconductor fabrication and, more particularly, to a system and method for forming thin film metal layers in vias.

### BACKGROUND OF THE INVENTION

In order to increase contrast for digital micromirror devices (“DMDs”), the individual mirror vias need to be made smaller. Forming thin film metal layers in these smaller vias with a long throw physical vapor deposition (“PVD”) process results in an asymmetry problem for the vias as the location of the vias appears to move toward the center of the wafer. The asymmetry leads to problems with subsequent photolithography alignment problems.

### SUMMARY OF THE INVENTION

In one embodiment, a method for forming a metal layer in a via of a semiconductor device includes providing a substrate, the substrate having a plurality of vias formed therein, forming a first portion of a metal layer outwardly from the substrate using a long throw sputtering process, and forming a second portion of the metal layer outwardly form the first portion of the metal layer using a short throw sputtering process. The first and second portions of the metal layer equal a total thickness of the metal layer.

Depending on the specific features implemented, particular embodiments of the present invention may exhibit some, none or all of the following technical advantages. Various embodiments may be capable of preventing the asymmetry problem for the thin film metal layers in vias during DMD manufacturing that results from a long throw PVD sputtering process. Thus, alignment problems during subsequent photolithography may be eliminated. Excellent step coverage may also be obtained.

Other technical advantages are readily apparent to one skilled in the art from the following figures, descriptions, and claims.

### BRIEF DESCRIPTION OF THE DRAWINGS

For a more complete understanding of the invention and the advantages thereof, reference is now made to the following description, taken in conjunction with the accompanying drawings, wherein like reference numerals represent like parts, in which:

FIGS. 1A through 1D illustrate various stages of the forming of a thin film metal layer in a via according to one embodiment of the invention.

### DETAILED DESCRIPTION OF EXAMPLE EMBODIMENTS OF THE INVENTION

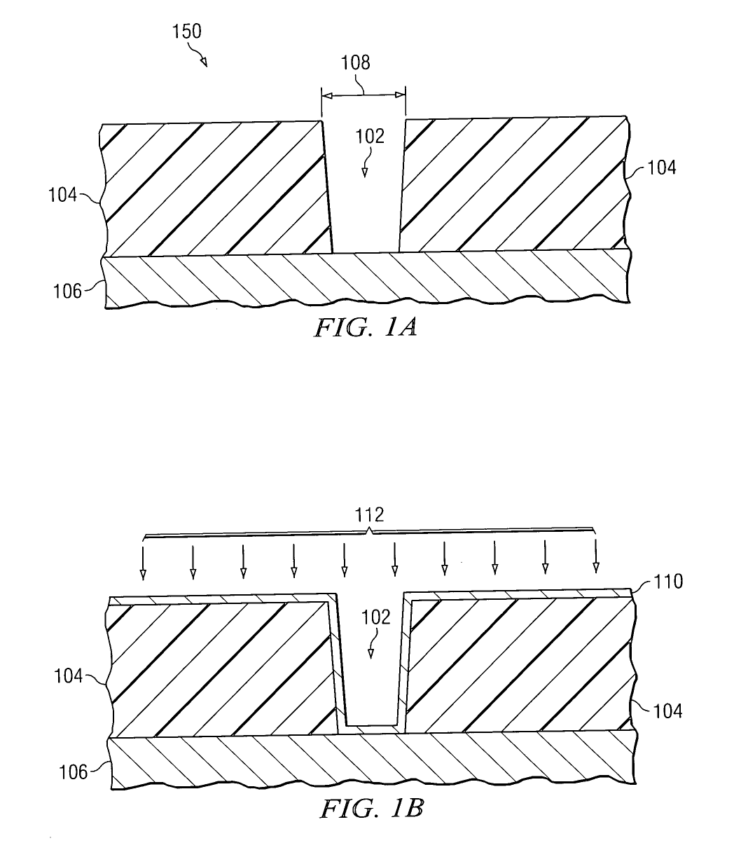

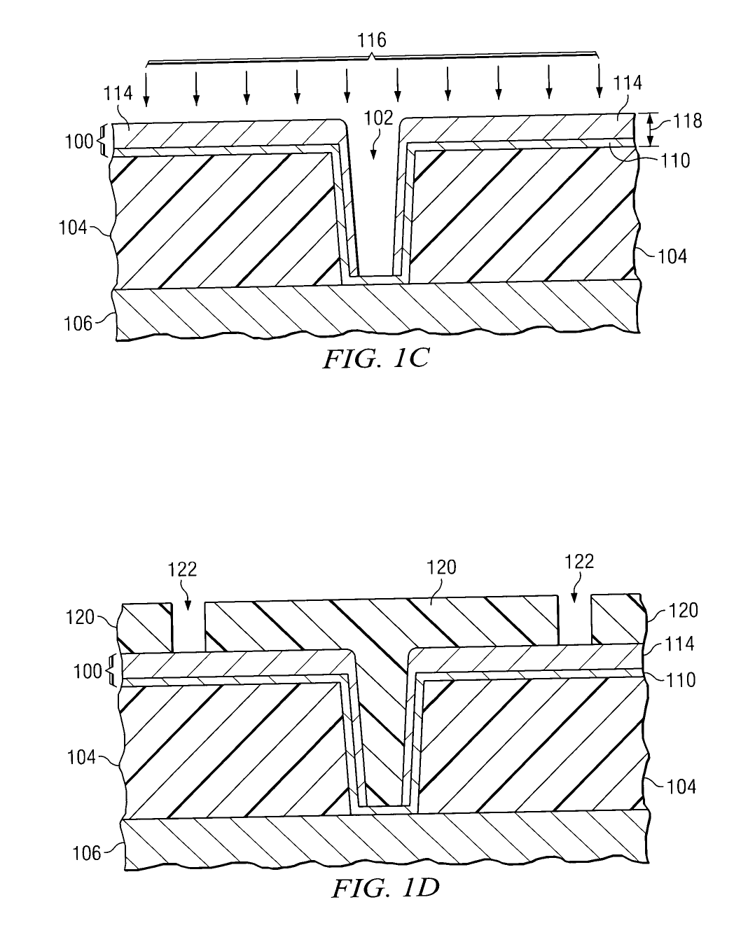

FIGS. 1A through 1D illustrate various stages of the forming of a film thin metal layer 100 (see FIG. 1D) in a via 102 (see FIG. 1A) of a semiconductor device 150 according to one embodiment of the invention. Although the method illustrated in FIGS. 1A through 1D is contemplated for use in any suitable semiconductor device, the method is particularly suitable for spatial light modulators, such as digital micro-mirror devices (DMDs). Hence, semiconductor device 150 as illustrated in FIGS. 1A through 1D is described herein as being a DMD.

Referring first to FIG. 1A, a substrate 104 having via 102 formed therein is illustrated. Although not explicitly illustrated, semiconductor device 150 typically includes a plurality of vias 102 formed therein, but only one via 102 is illustrated in FIG. 1A for clarity of description purposes. In one embodiment, substrate 104 is a suitable photoresist layer having any suitable thickness that is disposed outwardly from a metal layer 106 by any suitable semiconductor processing technique. However, the present invention contemplates any suitable material having any suitable thickness for substrate 104.

Via 102 is formed in substrate 104 using any suitable semiconductor processing technique and may have any suitable diameter 108. In one embodiment of the invention, a maximum diameter 108 of via 102 is approximately 1.0 micron. In some embodiments, via 102 may be non-circular.

Metal layer 106 is a portion of a DMD device that eventually forms the hinge metal, hinge support posts, and yoke of the DMD. Other layers below metal layer 106 also exist, but are not shown for clarity of description purposes. As is well known in the industry, these include but are not limited to a spacer layer, the “Metal 3” layer, and the CMOS structure of the DMD device. In embodiments of the present invention where semiconductor device 150 is not a DMD, metal layer 106 and the layers below metal layer 106 may not exist and may be replaced by other suitable layers or no layers at all.

Referring to FIG. 1B, a first portion 110 of metal layer 100 is formed outwardly from substrate 104 using a long throw sputtering process, as indicated by arrows 112. First portion 110 may have any suitable thickness and may be formed from any suitable metal, such as an aluminum alloy, which is common in a DMD device. As described in greater detail below, in one embodiment, the thickness of first portion 110 is between 20 and 30 percent of a total thickness 118 (FIG. 1C) of metal layer 100. In a more particular embodiment of the invention, the thickness of first portion 110 is approximately 25 percent of the total thickness 118 of metal layer 100. Because of the existence of via 102, first portion 110 also covers all of the surfaces of via 102 including the bottom of via 102, which contacts metal layer 106 in the illustrated embodiment.

The long throw sputtering process utilized is a physical vapor deposition (“PVD”) process that is a highly directional (anisotropic) sputtering process that results in excellent step coverage for semiconductor device 150. The term “long throw” is defined herein as having a minimum distance between the surface of substrate 104 and the metal target utilized in the sputtering process (not specifically illustrated) of 100 mm. Typically, the distance between the metal target and the surface of substrate 104 for a long throw sputtering process is about 150 mm. One specific example of a long throw sputtering process that may be utilized to form first portion 110 is the ALPS technology by Applied Materials®.

Referring to FIG. 1C, a second portion 114 of metal layer 100 is formed outwardly from first portion 110 using a short throw sputtering process, as indicated by arrows 116. Second portion 114 may have any suitable thickness and may be formed from any suitable metal, such as an aluminum alloy. Typically, both first portion 110 and section portion 114 are formed from the same type of metal. The thickness of both first portion 110 and section portion 114 make up total thickness 118 of metal layer 100. In an embodiment where semiconductor device 150 is a DMD, the total thickness 118 of metal layer 100 ensures that via 102 is not completely filled. In one embodiment of the invention, a thickness of second portion 114 is between 70 and 80 percent of the total thickness 118 of metal layer 100. In a more particular embodiment of the invention, a thickness of second portion 114 is approximately 75 percent of the total thickness 118 of metal layer 100.

The short throw sputtering process utilized for second portion 114 is also a PVD process that is a more isotropic sputtering process than the long throw sputtering process described above. The term “short throw” is defined herein as having a maximum distance between the surface of substrate 104 and the metal target of approximately 80 mm. Typically, the distance between the surface of substrate 104 and the metal target for a short throw sputtering process is between 35 and 70 mm. One specific example of a short throw sputtering process that may be utilized to form second portion 114 is the Durasource® process developed by Applied Materials®.

Referring to FIG. 1D, a photoresist layer 120 is formed outwardly from metal layer 100. Photo-resist layer 120 may have any suitable thickness and includes a plurality of etched areas 122 that are utilized to define the edges of the mirrors of a DMD device. In embodiments where semiconductor device 150 is a device different than a DMD, photoresist layer 120 may not be utilized and other suitable layers may be utilized. In an embodiment where semiconductor device 150 is a DMD, subsequent processing steps beyond that shown in FIG. 1D are not illustrated because their well known in the industry.

Thus, according to the teachings of the present invention as noted above, metal layer 100 is formed from two different sputtering processes, a long throw sputtering process to form first portion 110 followed by a short throw sputtering process to form second portion 114. The dual sputtering process described above eliminates any asymmetry problem of a strictly long throw sputtering process that causes photolithography alignment problems in the manufacturing of a DMD device, for example. Among other advantages, the long throw sputtering process 112 gives excellent step coverage while the short throw sputtering process 116 eliminates any asymmetry problem.

Although embodiments of the invention and their advantages are described in detail, a person skilled in the art could make various alterations, additions, and omissions without departing from the spirit and scope of the present invention, as defined by the appended claims.

What is claimed:

1. A method for forming a metal layer in a via of a semiconductor device, comprising:
providing a substrate, the substrate having a plurality of vias formed therein;
forming a first portion of a metal layer outwardly from the substrate using a long throw sputtering process; and
forming a second portion of the metal layer outwardly form the first portion of the metal layer using a short throw sputtering process, the first and second portions of the metal layer equaling a total thickness of the metal layer.

2. The method of claim 1, wherein the semiconductor device comprises a digital micro-mirror device.

3. The method of claim 1, wherein the metal layer is formed from an aluminum alloy.

4. The method of claim 1, wherein the first portion comprises between twenty and thirty percent of the total thickness of the metal layer and the second portion comprises between seventy and eighty percent of the total thickness of the metal layer.

5. The method of claim 1, wherein the first portion comprises approximately twenty-five percent of the total thickness of the metal layer and the second portion comprises approximately seventy-five percent of the total thickness of the metal layer.

6. The method of claim 1, wherein the substrate comprises a photoresist layer.

7. The method of claim 1, further comprising forming a photoresist layer outwardly from the metal layer.

8. The method of claim 1, wherein a maximum diameter of the vias is no more than approximately 1.0 micron.

9. A system for forming a metal layer in a via of a semiconductor device, comprising:
a substrate having a plurality of vias formed therein;
a long throw sputtering process forming a first portion of a metal layer outwardly from the substrate; and
a short throw sputtering process forming a second portion of the metal layer outwardly form the first portion of the metal layer, the first and second portions of the metal layer equaling a total thickness of the metal layer.

10. The system of claim 9, wherein the semiconductor device comprises a digital micro-mirror device.

11. The system of claim 9, wherein the metal layer is formed from an aluminum alloy.

12. The system of claim 9, wherein the first portion comprises between twenty and thirty percent of the total thickness of the metal layer and the second portion comprises between seventy and eighty percent of the total thickness of the metal layer.

13. The system of claim 9, wherein the first portion comprises approximately twenty-five percent of the total thickness of the metal layer and the second portion comprises approximately seventy-five percent of the total thickness of the metal layer.

14. The system of claim 9, wherein the substrate comprises a photoresist layer.

15. The system of claim 9, further comprising a photoresist layer formed outwardly from the metal layer.

16. The system of claim 9, wherein a maximum diameter of the vias is no more than approximately 1.0 micron.

17. A method for forming a metal layer in a via of a digital micro-mirror device, comprising:
providing a first photoresist layer, the first photoresist layer having a plurality of vias formed therein;
forming a first portion of a metal layer outwardly from the first photoresist layer using a long throw sputtering process;
forming a second portion of the metal layer outwardly form the first portion of the metal layer using a short throw sputtering process;
the first portion comprising between twenty and thirty percent of a total thickness of the metal layer and the second portion comprising between seventy and eighty percent of the total thickness of the metal layer; and
forming a second photoresist layer outwardly from the metal layer.

18. The method of claim 17, wherein the metal layer is formed from an aluminum alloy.

19. The method of claim 17, wherein the first portion comprises approximately twenty-five percent of the total thickness of the metal layer and the second portion comprises approximately seventy-five percent of the total thickness of the metal layer.

20. The method of claim 17, wherein a maximum diameter of the vias is no more than approximately 1.0 micron.
